(19) United States
(12) Patent Application Publication
(10) Pub. No.: US 2025/0379108 A1
(43) Pub. Date: Dec. 11, 2025

(54) SEMICONDUCTOR DEVICE AND DETECTION METHOD THEREOF

(71) Applicant: Winbond Electronics Corp., Taichung City (TW)

(72) Inventor: Chih-Tung Tang, Hsinchu (TW)

(73) Assignee: Winbond Electronics Corp., Taichung City (TW)

(21) Appl. No.: 19/053,429

(22) Filed: Feb. 14, 2025

(30) Foreign Application Priority Data
Jun. 7, 2024 (TW) 113121368

(51) Int. Cl. H01L 21/66; H01L 23/498

(52) U.S. Cl. CPC H01L 22/32; H01L 23/49827; H01L 23/49838

(57) ABSTRACT

Disclosed are a semiconductor device and a detection method thereof. The detection method includes the following steps: applying a control signal to a first open sleeve TSV formed in a substrate; writing a data signal to a second open sleeve TSV formed in the substrate, wherein a bottom of the second open sleeve TSV has a doped region; reading an output signal from the second open sleeve TSV; and determining whether the second open sleeve TSV is defective according to the output signal.

### CROSS-REFERENCE TO RELATED APPLICATION

This application claims the priority benefit of Taiwan application serial no. 113121368, filed on Jun. 7, 2024. The entirety of the above-mentioned patent application is hereby incorporated by reference herein and made a part of this specification.

### BACKGROUND

### Technical Field

The present disclosure relates to a device, and in particular, to a semiconductor device and a detection method thereof.

### Description of Related Art

In conventional three-dimensional integrated circuits, for defect detection for blind through silicon vias in the substrate, signal detection is normally performed only after the multi-layer substrate is packaged and wired. Test costs will rise as the number of stacked substrates increases, repairs will also be more difficult, and production efficiency will be low. If there is a defect at the bottom of the blind through silicon via in the substrate, that is, the bottom of the metal layer of the blind through silicon via is not completely filled in the bottom of the through via, it is difficult to detect this type of defect using conventional detection methods.

### SUMMARY

The present disclosure provides a semiconductor device and a detection method thereof, which may effectively detect whether the through silicon via (TSV) is defective.

A detection method of a semiconductor device of the present disclosure includes the following steps: applying a control signal to a first open sleeve TSV formed in a substrate; writing a data signal to a second open sleeve TSV formed in the substrate, wherein a bottom of the second open sleeve TSV has a doped region; reading an output signal from the second open sleeve TSV; and determining whether the second open sleeve TSV is defective according to the output signal.

The semiconductor device of the present disclosure includes a substrate, a first open sleeve TSV, and a second open sleeve TSV. A first open sleeve TSV is formed in the substrate. A second open sleeve TSV is formed in the substrate, and a bottom of the second open sleeve TSV has a doped region.

Based on the above, the semiconductor device of the present disclosure may form a first open sleeve TSV and a second open sleeve TSV in the substrate, and the bottom of the second open sleeve TSV has a doped region. The detection method of the present disclosure may be used along with the first open sleeve TSV to detect whether the second open sleeve TSV is defective.

In order to make the above-mentioned features and advantages of the present disclosure more clear and easy to understand, embodiments are given below and described in detail with reference to the attached drawings.

### BRIEF DESCRIPTION OF THE DRAWINGS

FIG. 1 is a schematic view of a semiconductor device according to an embodiment of the present disclosure.

FIG. 2, FIG. 4 and FIG. 6 are schematic views of equivalent circuits according to an embodiment of the present disclosure.

FIG. 3 is a flow chart of a detection method of a semiconductor device according to an embodiment of the present disclosure.

FIG. 5 and FIG. 7 are schematic views of output signals according to an embodiment of the present disclosure.

FIG. 8 is a circuit diagram of a semiconductor device according to an embodiment of the present disclosure.

### DESCRIPTION OF THE EMBODIMENTS

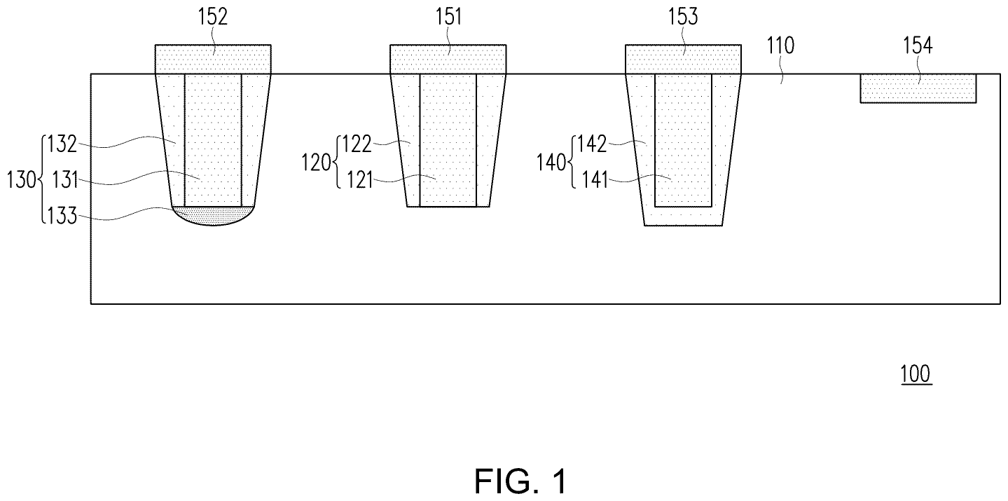

Referring to FIG. 1, a semiconductor device 100 includes a substrate 110, a first open sleeve through silicon via (open sleeve TSV) 120, and a second open TSV 130. The first open sleeve TSV 120 and the second open sleeve TSV 130 are formed on the substrate 110. In this embodiment, the first open sleeve TSV 120 includes a metal layer 121 and an insulating layer 122, wherein the insulating layer 122 is formed between a side surface of the metal layer 121 and the substrate 110 (the insulating layer 122 wraps the side surface of the metal layer 121), and the bottom of the metal layer 121 is connected to the substrate 110. In this embodiment, the second open sleeve TSV 130 includes a metal layer 131, an insulating layer 132 and a doped region 133, wherein the insulating layer 132 is formed between the side surface of the metal layer 131 and the substrate 110 (the insulating layer 132 wraps the side surface of the metal layer 131), and the doped region 133 is formed at the bottom of the metal layer 131.

The semiconductor device 100 further includes a blind through silicon via (blind TSV) 140. The blind TSV 140 includes a metal layer 141 and an insulating layer 142, wherein the insulating layer 142 wraps the side surface and bottom of the metal layer 141 to isolate the metal layer 141 from the substrate 110. In an embodiment, the semiconductor device 100 may not include the blind TSV 140. Electrodes 151 to 153 and a substrate tap 154 are further formed on the tops of the first open sleeve TSV 120, the second open sleeve TSV 130 and the blind TSV 140 (that is, the openings on the surface of the substrate 110). In this embodiment, the substrate tap 154 may be a P-type semiconductor material.

In this embodiment, the semiconductor device 100 may be, for example, one of the layers of a multi-layer substrate of a three-dimensional integrated circuit (3D IC). The substrate 110 is a single-layer material substrate. Under the circumstances, before the wiring stage prior to packaging of the three-dimensional integrated circuit, the second open sleeve TSV 130 of the semiconductor device 100 may be detected to determine whether the second open sleeve TSV 130 is defective. In this embodiment, the substrate 110 may be a P-type silicon substrate, and the doped region 133 may form an N-type semiconductor, but the disclosure is not limited thereto. In an embodiment, the substrate 110 may be an N-type silicon substrate, and the doped region 133 may form a P-type semiconductor. In this embodiment, the doped region 133 may be implemented through a semiconductor process of ion implantation.

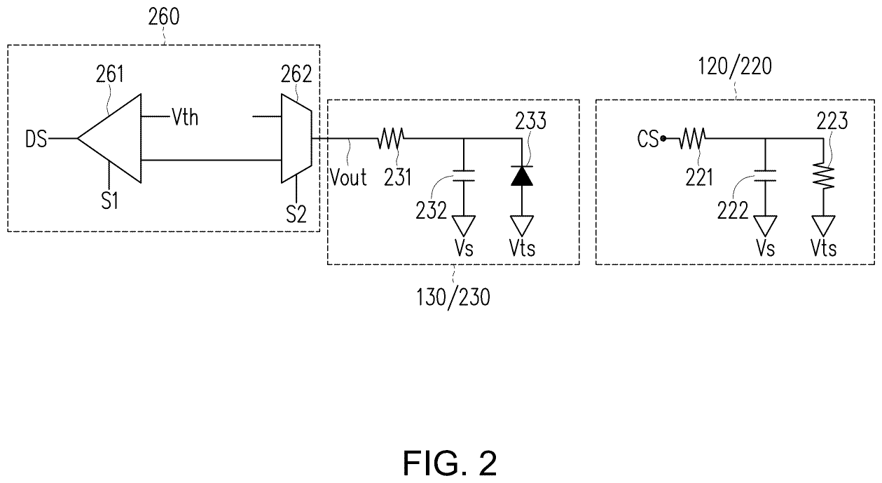

Referring to FIG. 1 and FIG. 2, the first open sleeve TSV 120 may be represented by an equivalent circuit 220 as shown in FIG. 2, and the second open sleeve TSV 130 may be represented by an equivalent circuit 230 as shown in FIG. 2. The semiconductor device 100 may further include a detection circuit 260. The detection circuit 260 may include a comparator 261 and a multiplexer 262. The comparator 261 and the multiplexer 262 are formed in the substrate 110. In this embodiment, the first input terminal of the comparator 261 receives the threshold voltage Vth. The output terminal of the comparator 261 may output the comparison result DS. The input terminal of the multiplexer 262 is coupled to the equivalent circuit 230 of the second open sleeve TSV 130 as shown in FIG. 1. The first output terminal of the multiplexer 262 is coupled to a functional circuit (not shown). The second output terminal of the multiplexer 262 is coupled to the second input terminal of the comparator 261. The comparator 261 may be a sensing amplifier (SA) and may receive the sensing enable signal S1. The multiplexer 262 may also receive the mode switching signal S2.

The equivalent circuit 220 of the first open sleeve TSV 120 may include a resistor 221, a capacitor 222 and a resistor 223. The resistor 221 is connected in series with the capacitor 222 and the resistor 223 connected in parallel. The first terminal of the capacitor 222 is coupled to the first terminal of the resistor 221, and the second terminal of the capacitor 222 is coupled to the substrate voltage Vs. The first terminal of the resistor 223 is coupled to the first terminal of the resistor 221, and the second terminal of the resistor 223 may provide the substrate control voltage Vts. In an embodiment, the substrate control voltage Vts may be equal to the substrate voltage Vs, but the disclosure is not limited thereto.

The equivalent circuit 230 of the second open sleeve TSV 130 may include a resistor 231, a capacitor 232, and a diode 233. The doped region 133 may be equivalent to the diode 233. The resistor 231 is connected in series with the capacitor 232 and the diode 233 connected in parallel. The first terminal of the capacitor 232 is coupled to the first terminal of the resistor 231, and the second terminal of the capacitor 232 is coupled to the substrate voltage Vs. The first terminal of the diode 233 is coupled to the first terminal of the resistor 231, and the second terminal of the diode 233 is coupled to the substrate control voltage Vts. The second terminal of the resistor 231 is coupled to the input terminal of the multiplexer 262.

However, it should be noted that when the second open sleeve TSV 130 has an open-circuit fault, the current flowing through the doped region 133 will be blocked, resulting in the inability to quickly take away (release) the charge of the second open sleeve TSV 130. In contrast, when the second open sleeve TSV 130 does not have an open-circuit fault, the current flowing through the doped region 133 will not be blocked, so the charge of the second open sleeve TSV 130 may be quickly taken away. In other words, whether the second open sleeve TSV 130 has an open-circuit fault may be determined based on the discharge effect of the second open sleeve TSV 130.

The multiplexer 262 may decide to operate in the detection mode or the normal mode according to the mode switching signal S2. When the multiplexer 262 operates in the detection mode, the multiplexer 262 may provide the output signal Vout provided by the second open sleeve TSV 130 to the second input terminal of the comparator 261. Moreover, when the comparator 261 is triggered by the sensing enable signal S1, the comparator 261 may compare the current output voltage of the output signal Vout with the threshold voltage Vth to output a comparison result DS. When the multiplexer 262 operates in the normal mode, the multiplexer 262 may provide the output signal Vout provided by the second open sleeve TSV 130 to the functional circuit.

In this embodiment, the functional circuit may be formed in the substrate 110, and may be used for the internal functional circuit after the three-dimensional integrated circuit is packaged. In other words, the multiplexer 262 of the detection circuit 260 may be applied to the detection function in the manufacturing stage, and may also be applied to the internal functional circuit of the actual product. In an embodiment, the detection circuit 260 may also include other signal generation circuits and signal processing circuits.

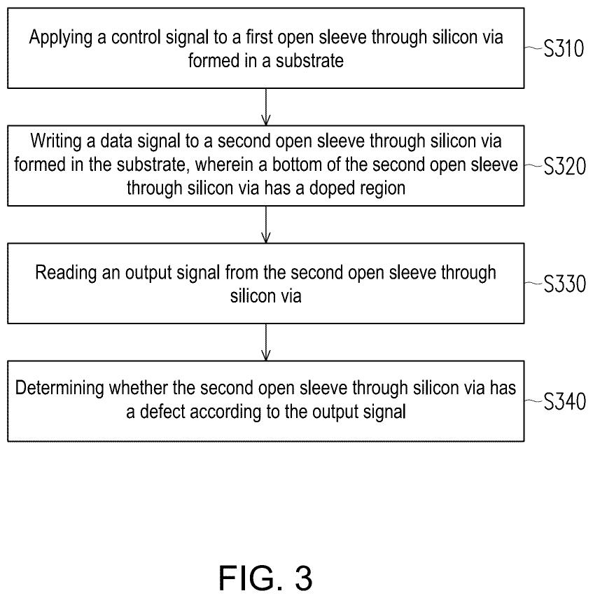

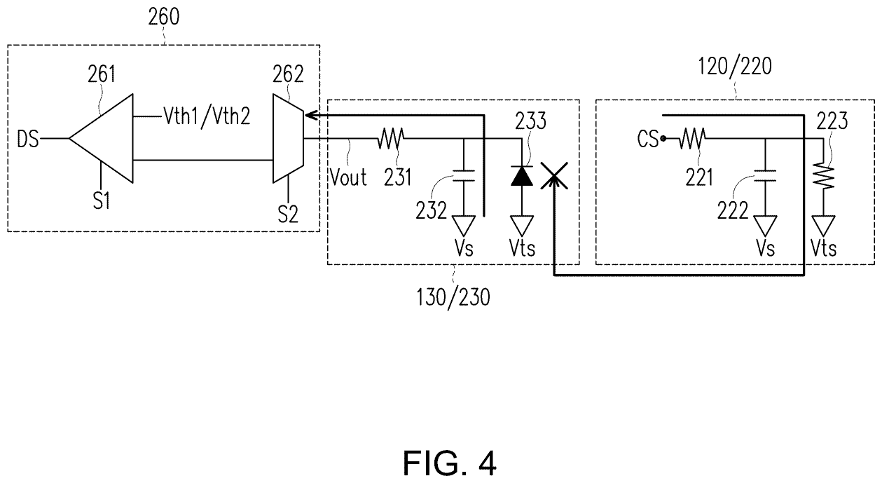

Referring to FIG. 1 to FIG. 3, the semiconductor device 100 may perform the detection method with steps S310 to S340 as follows. In step S310, the detection circuit 260 may apply the control signal CS to the first open sleeve TSV 120 formed in the substrate 110. As shown in FIG. 2, the control signal CS may be applied to the second terminal of the resistor 221 in the equivalent circuit 220 so that the resistor 221 and the resistor 223 may form a discharge path. In this way, a cross voltage may be formed between the first terminal and the second terminal of the resistor 223, so that the second terminal of the resistor 223 may provide the substrate control voltage Vts.

In step S320, the detection circuit 260 may write the data signal to the second open sleeve TSV 130 formed in the substrate 110, wherein the bottom of the second open sleeve TSV 130 has a doped region 133. As shown in FIG. 2, the data signal may be applied to the second terminal of the resistor 231 in the equivalent circuit 230, and the data voltage may be written into the capacitor 232. Based on the energy storage result of the capacitor 232, the capacitor 232 may be discharged through the resistor 231 to generate the output signal Vout.

In step S330, the detection circuit 260 may read the output signal Vout from the second open sleeve TSV 130. In step S340, the detection circuit 260 may determine whether the second open sleeve TSV 130 is defective according to the output signal Vout.

It is worth noting that the defects described in the present disclosure may include a short-circuit fault and two open-circuit faults, which will be described in detail in the following embodiments.

Referring first to FIG. 4, in the first detection mode, the control signal CS may be applied to the second terminal of the resistor 221 in the equivalent circuit 220, wherein the control signal CS may be a negative voltage. Therefore, the resistor 221 and the resistor 223 may form a discharge path, and the second terminal of the resistor 223 may provide the substrate control voltage Vts. Therefore, the diode 233 in the equivalent circuit 230 may be operated in a cut-off state or have a lower leakage current. In other words, when a negative voltage is applied to the first open sleeve TSV 120, the first open sleeve TSV 120 may be equivalent to the resistor 221 connected in series with the capacitor 222 and the resistor 223 connected in parallel, and the second open sleeve TSV 130 may be equivalent to the resistor 231 connected in series with the capacitor 232. Furthermore, the detection circuit 260 may write the data signal to the capacitor 232. Then, since the resistor 231 and the capacitor 232 may form a discharge path, the second terminal of the resistor 231 may output the output signal Vout.

As shown in FIG. 1, if the second open sleeve TSV 130 has a short-circuit fault, the voltage level of the output voltage of the output signal Vout will decrease rapidly during the discharge process. It should be noted that the short-circuit fault in this embodiment might occur, for example, because the insulating layer 132 of the second open sleeve TSV 130 does not properly isolate the metal layer 131 from the substrate 110, causing the side surface of the metal layer 131 to be in contact with the substrate 110, and further forming another discharge path. If the second open sleeve TSV 130 has an open-circuit fault, the voltage level of the output voltage of the output signal Vout will decrease slowly during the discharge process. It should be noted that the open-circuit fault in this embodiment might occur, for example, because the metal layer 131 of the second open sleeve TSV 130 is not completely filled in the through via and there are gaps in between, which decreases the discharge effect.

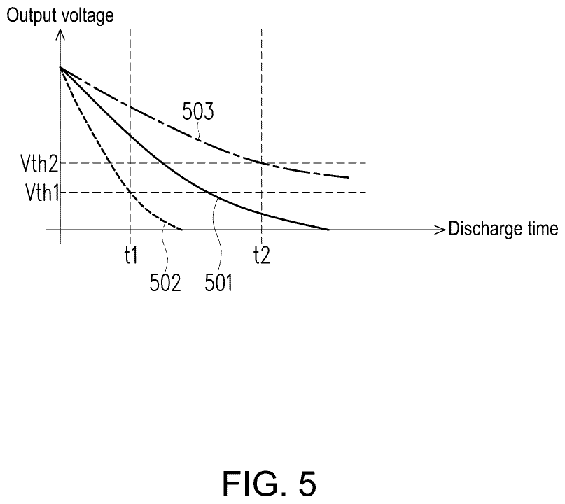

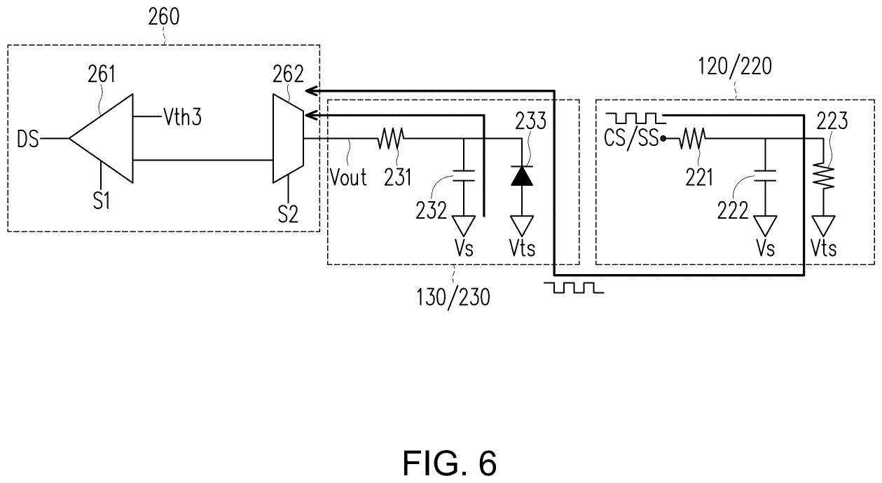

Specifically, referring to FIG. 4 and FIG. 5, the multiplexer 262 may provide the output signal Vout to the second input terminal of the comparator 261 according to the mode switching signal S2. At the first detection time point t1, the comparator 261 may receive the sensing enable signal S1 and the first threshold voltage Vth1. The comparator 261 may determine whether the output voltage Vx of the output signal Vout at the first detection time point t1 is higher than the first threshold voltage Vth1. When the output voltage Vx is higher than the first threshold voltage Vth1, it may be determined that the second open sleeve TSV 130 does not have a short-circuit fault. When the output voltage Vx is lower than or equal to the first threshold voltage Vth1, it may be determined that the second open sleeve TSV 130 has a short-circuit fault.

Further, as shown in FIG. 5, if the second open sleeve TSV 130 does not have a short-circuit fault, the discharge trend of the output signal Vout may be like the curve 501 or the curve 503, in which case the output voltage Vx will be higher than the first threshold voltage Vth1 at the first detection time point t1. On the contrary, if the second open sleeve TSV 130 has a short-circuit fault, the discharge trend of the output signal Vout may be like the curve 502, in which case the output voltage Vx will be lower than or equal to the first threshold voltage Vth1 at the first detection time point t1.

Then, at the second detection time point t2, the comparator 261 may receive the sensing enable signal S1 and the second threshold voltage Vth2. The comparator 261 may determine whether the output voltage Vx of the output signal Vout at the second detection time point t2 is lower than the second threshold voltage Vth2. When the output voltage Vx is lower than the second threshold voltage Vth2, it may be determined that the second open sleeve TSV 130 does not have an open-circuit fault. When the output voltage Vx is higher than or equal to the second threshold voltage Vth2, it may be determined that the second open sleeve TSV 130 has an open-circuit fault. The second threshold voltage Vth2 is higher than the first threshold voltage Vth1.

Further, as shown in FIG. 5, if the second open sleeve TSV 130 does not have an open-circuit fault, the discharge trend of the output signal Vout may be like the curve 501 or the curve 502, in which case the output voltage Vx will be lower than the second threshold voltage Vth2 at the second detection time point t2. On the contrary, if the second open sleeve TSV 130 has an open-circuit fault, the discharge trend of the output signal Vout may be like the curve 503, in which case the output voltage Vx will be higher than or equal to the second threshold voltage Vth2 at the second detection time point t2.

Therefore, the semiconductor device 100 and the detection method of this embodiment may effectively detect whether the second open sleeve TSV 130 has short-circuit faults and open-circuit faults.

Referring to FIG. 6 first, in the second detection mode, the control signal CS may be applied to the second terminal of the resistor 221 in the equivalent circuit 220, wherein the control signal CS may first be a negative voltage. In that case, the resistor 221 and the resistor 223 may form a discharge path, and the second terminal of the resistor 223 may provide the substrate control voltage Vts. Furthermore, the detection circuit 260 may write the data signal to the capacitor 232. Next, while the test circuit 260 reads the output signal Vout from the second open sleeve TSV 130, the detection circuit 260 may apply a toggling signal SS to the second terminal of the resistor 221 in the equivalent circuit 220 of the first open sleeve TSV 120. The second terminal of the resistor 223 may accordingly provide the control voltage Vts of the substrate having a corresponding toggling waveform to the diode 233. Therefore, when the second open sleeve TSV 130 has an open-circuit fault, the current flowing through the doped region 133 will be blocked, causing that the charge of the second open sleeve TSV 130 cannot be quickly taken away. In contrast, when the second open sleeve TSV 130 does not have an open-circuit fault, the current flowing through the doped region 133 will not be blocked, so the charge of the second open sleeve TSV 130 may be quickly taken away. In other words, whether the second open sleeve TSV 130 has an open-circuit fault may be determined based on the discharge effect of the second open sleeve TSV 130.

Under the circumstances, it is worth noting that, as shown in FIG. 1, if the second open sleeve TSV 130 has an open-circuit fault, the voltage level of the output voltage of the output signal Vout will normally decrease during the discharge process. It should be noted that the open-circuit fault in this embodiment may occur, for example, because the bottom of the metal layer 131 of the second open sleeve TSV 130 is not completely filled in the bottom of the through via, resulting in a gap generated between the bottom of the metal layer 131 and the doped region 133, which decreases the discharge effect.

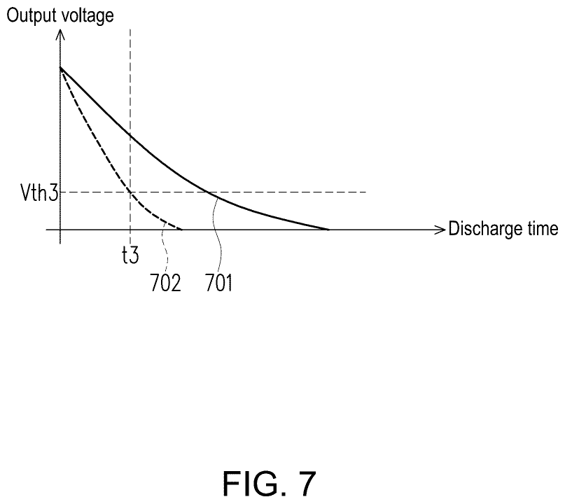

Specifically, referring to FIG. 6 and FIG. 7, the multiplexer 262 may provide the output signal Vout to the second input terminal of the comparator 261 according to the mode switching signal S2. At the third detection time point t3, the comparator 261 may receive the sensing enable signal S1 and the third threshold voltage Vth3. The comparator 261 may determine whether the output voltage Vx of the output signal Vout at the third detection time point t3 is higher than the third threshold voltage Vth3. When the output voltage Vx is higher than the third threshold voltage Vth3, it may be determined that the second open sleeve TSV 130 has an open-circuit fault. When the output voltage Vx is lower than or equal to the third threshold voltage Vth3, it may be determined that the second open sleeve TSV 130 does not have an open-circuit fault.

Further, as shown in FIG. 7, if the second open sleeve TSV 130 has an open-circuit fault, the discharge trend of the output signal Vout may be like the curve 701, in which case the output voltage Vx will be higher than the third threshold voltage Vth3 at the third detection time point t3. On the contrary, if the second open sleeve TSV 130 does not have an open-circuit fault (discharge is accelerated due to the influence of the leakage current of the equivalent diode), the discharge trend of the output signal Vout may be like the curve 702, in which case the output voltage Vx will be lower than or equal to the third threshold voltage Vth3 at the third detection time point t3.

Therefore, the semiconductor device 100 and the detection method of this embodiment may effectively detect whether the second open sleeve TSV 130 has an open-circuit fault near the bottom of the through via.

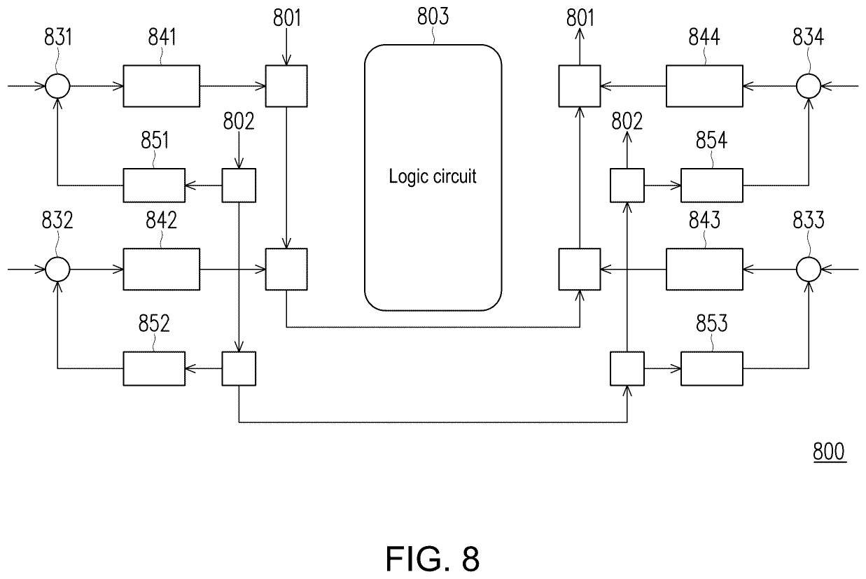

Referring to FIG. 8, in some embodiments of the present disclosure, the substrate of the semiconductor device 800 may further include a scan chain 801, a logic circuit 803, a plurality of blind TSVs 831 to 834, and a plurality of comparators 841 to 844 formed thereon. The logic circuit 803 may be, for example, a memory circuit, but the disclosure is not limited thereto. The scan chain 801, the plurality of blind TSVs 831 to 834, and the plurality of comparators 841 to 844 may be arranged around the logic circuit 803. The blind TSVs 831 to 834 may be coupled to the scan chain 801 through the comparators 841 to 844.

Furthermore, the substrate of the semiconductor device 800 may further include a write chain 802 and a plurality of drivers 851 to 854, and the blind TSVs 831 to 834 may be coupled to the write chain 802 through the drivers 851 to 854. The write chain 802 and the plurality of drivers 851 to 854 may be arranged around the logic circuit 803. It should be noted that the scan chain 801 and the write chain 802 may be used as signal transmission paths for the logic circuit 803 to implement data reading and data writing. The blind TSVs 831 to 834 may respectively include at least one of the first open sleeve TSV 120, the second open sleeve TSV 130 and the blind TSV 140 described in the embodiment of FIG. 1.

In this embodiment, as in the detection scenarios described in the above embodiments, the control signal may be provided to the drivers 851 to 854 through the write chain 802, so that the drivers 851 to 854 may effectively adjust the substrate control voltage through the blind TSVs 831 to 834. Then, the comparators 841 to 844 may generate corresponding multiple detection results according to the multiple output signals of the blind TSVs 831 to 834 respectively, and the multiple detection results may be read out by the scan chain 801. In other words, the scan chain 801 and the write chain 802 are used to detect whether the blind TSVs 831 to 834 are defective. Moreover, after the semiconductor device 800 is packaged (becomes an actual product), the write data may be provided to the blind TSVs 831 to 834 through the write chain 802, and the scan chain 801 may read the read data of the blind TSVs 831 to 834. In this way, the scan chain 801 and the write chain 802 may also realize the signal transmission function of the blind TSVs 831 to 834.

In summary, the semiconductor device of the present disclosure may form a first open sleeve TSV and a second open sleeve TSV in a substrate, and the bottom of the second open sleeve TSV has a doped region. The detection method of the present disclosure may provide a substrate control voltage through the first open sleeve TSV, so as to detect whether the second open sleeve TSV is defective.

Although the present disclosure has been disclosed above through embodiments, it is not intended to limit the present disclosure. Anyone with ordinary knowledge in the technical field can make some modifications and refinement without departing from the spirit and scope of the present disclosure. Therefore, the scope to be protected by the present disclosure shall be determined by the appended claims.

What is claimed is:

1. A detection method of a semiconductor device, comprising the following:
applying a control signal to a first open sleeve through silicon via (open sleeve TSV) formed in a substrate;
writing a data signal to a second open sleeve TSV formed in the substrate, wherein a bottom of the second open sleeve TSV has a doped region;
reading an output signal from the second open sleeve TSV; and
determining whether the second open sleeve TSV is defective according to the output signal.

2. The detection method of the semiconductor device according to claim 1, wherein the step of determining whether the second open sleeve TSV is defective according to the output signal comprises:
determining whether a first output voltage of the output signal at a first detection time point is higher than a first threshold voltage;
when the first output voltage is higher than the first threshold voltage, determining that the second open sleeve TSV does not have a short-circuit fault; and
when the first output voltage is lower than or equal to the first threshold voltage, determining that the second open sleeve TSV has the short-circuit fault.

3. The detection method of the semiconductor device according to claim 2, wherein the step of determining whether the second open sleeve TSV is defective according to the output signal further comprises:
determining whether a second output voltage of the output signal at a second detection time point is lower than a second threshold voltage;
when the second output voltage is lower than the second threshold voltage, determining that the second open sleeve TSV does not have an open-circuit fault; and
when the second output voltage is higher than or equal to the second threshold voltage, determining that the second open sleeve TSV has the open-circuit fault, wherein the second threshold voltage is higher than the first threshold voltage.

4. The detection method of the semiconductor device according to claim 1, wherein when the control signal is applied to the first open sleeve TSV, the first open sleeve TSV is equivalent to a first resistor connected in series with a first capacitor and a second resistor connected in parallel, and the second open sleeve TSV is equivalent to another first resistor connected in series with another first capacitor.

5. The detection method of the semiconductor device according to claim 4, wherein the data signal is written to the another first capacitor, the another first capacitor and the another first resistor form a discharge path, and one terminal of the another first resistor outputs the output signal.

6. The detection method of the semiconductor device according to claim 4, wherein the step of reading the output signal from the second open sleeve TSV further comprises:
applying a toggling signal to the first open sleeve TSV.

7. The detection method of the semiconductor device according to claim 6, wherein one terminal of the first resistor accordingly provides a control voltage of the substrate having a corresponding toggling waveform to a diode equivalent to the second open sleeve TSV.

8. The detection method of the semiconductor device according to claim 6, wherein the step of determining whether the second open sleeve TSV is defective according to the output signal comprises:
determining whether a third output voltage of the output signal at a third detection time point is higher than a third threshold voltage;
when the third output voltage is higher than the third threshold voltage, determining that the second open sleeve TSV has an open-circuit fault; and
when the third output voltage is lower than or equal to the third threshold voltage, determining that the second open sleeve TSV does not have the open-circuit fault.

9. The detection method of the semiconductor device according to claim 6, wherein in response to the second open sleeve TSV having an open-circuit fault, a current flowing through the doped region is blocked, so that a charge of the second open sleeve TSV is not able to be taken away quickly,
in response to that the second open sleeve TSV does not have the open-circuit fault, the current flowing through the doped region is not blocked, so that the charge of the second open sleeve TSV is quickly taken away.

10. The detection method of the semiconductor device according to claim 1, wherein the semiconductor device further comprises:
a detection circuit coupled to the second open sleeve TSV and receiving the output signal, wherein the detection circuit comprises:
a comparator, wherein a first input terminal of the comparator receives a threshold voltage; and
a multiplexer, wherein an input terminal of the multiplexer is coupled to the second open sleeve TSV to receive the output signal, a first output terminal of the multiplexer is coupled to a functional circuit, and a second output terminal of the multiplexer is coupled to a second input terminal of the comparator.

11. The detection method of the semiconductor device according to claim 1, wherein the substrate further comprises a scan chain, a plurality of comparators and a plurality of second open sleeve TSVs, and the plurality of second open sleeve TSVs are coupled to the scan chain through the plurality of comparators.

12. The detection method of the semiconductor device according to claim 11, wherein the substrate further comprises a write chain and a plurality of drivers, and the plurality of second open sleeve TSVs are coupled to the write chain through the plurality of drivers.

13. A semiconductor device, comprising:
a substrate;
a first open sleeve TSV formed in the substrate, and the first open sleeve TSV comprising:
a first metal layer; and
a first insulating layer, wherein the first insulating layer is formed between a side surface of the first metal layer and the substrate, and a bottom of the first metal layer is connected to the substrate; and
a second open sleeve TSV formed in the substrate, and the second open sleeve TSV comprising:
a second metal layer;
a second insulating layer; and
a doped region, wherein the second insulating layer is formed between a side surface of the second metal layer and the substrate, and the doped region is formed at a bottom of the second metal layer.

14. The semiconductor device according to claim 13, wherein when a control signal is applied to the first open sleeve TSV, the first open sleeve TSV is equivalent to a first resistor connected in series with a first capacitor and a second resistor connected in parallel, and the second open sleeve TSV is equivalent to another first resistor connected in series with another first capacitor.

15. The semiconductor device according to claim 14, wherein the control signal is a negative voltage.

16. The semiconductor device according to claim 13, further comprising:
a detection circuit coupled to the second open sleeve TSV and receiving an output signal, wherein the detection circuit comprises:
a comparator, wherein a first input terminal of the comparator receives a threshold voltage; and
a multiplexer, wherein an input terminal of the multiplexer is coupled to the second open sleeve TSV to receive the output signal, a first output terminal of the multiplexer is coupled to a functional circuit, and a second output terminal of the multiplexer is coupled to a second input terminal of the comparator.

17. The semiconductor device according to claim 13, wherein the substrate further comprises a scan chain, a plurality of comparators and a plurality of second open sleeve TSVs, and the plurality of second open sleeve TSVs are coupled to the scan chain through the plurality of comparators.

18. The semiconductor device according to claim 17, wherein the substrate further comprises a write chain and a plurality of drivers, and the plurality of second open sleeve TSVs are coupled to the write chain through the plurality of drivers.

19. The semiconductor device according to claim 13, wherein the substrate is a P-type silicon substrate, and the doped region forms an N-type semiconductor.

20. The semiconductor device according to claim 13, wherein the substrate is a single-layer material substrate.
